(19) United States
(12) Patent Application Publication
(10) Pub. No.: US 2025/0380435 A1
(43) Pub. Date: Dec. 11, 2025

(54) METAL-INSULATOR-METAL DEVICE STRUCTURES AND METHODS OF FORMING THE SAME

(71) Applicant: TAIWAN SEMICONDUCTOR MANUFACTURING COMPANY, LTD., Hsinchu (TW)

(72) Inventors: Cheng-I CHIANG, Taoyuan (TW); Yong-Ping CHAN, Hsinchu (TW); Jung-Hau SHIU, New Taipei City (TW)

(21) Appl. No.: 18/736,659

(22) Filed: Jun. 7, 2024

(51) Int. Cl. H01G 4/10

(52) U.S. Cl. CPC H10D 1/696; H01G 4/10

(57) ABSTRACT

Embodiments of present disclosure provide a MIM capacitor device structure including a first conductive layer disposed over a substrate and a dielectric stack disposed on the first conductive layer. The dielectric stack includes a first dielectric layer disposed on the first conductive layer, and the first dielectric layer has a first oxygen concentration. The dielectric stack further includes a high-k dielectric layer disposed on the first dielectric layer, and the high-k dielectric layer has a second oxygen concentration different from the first oxygen concentration. The dielectric stack further includes a second dielectric layer disposed on the high-k dielectric layer, and the second dielectric layer has a third oxygen concentration different from the second oxygen concentration. The structure further includes a second conductive layer disposed on the dielectric stack.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of IC evolution, functional density (i.e., the number of interconnected devices per chip area) has generally increased while geometric size (i.e., the smallest component that can be created using a fabrication process) has decreased.

Many of the ICs involve capacitive structures to store a charge in a variety of semiconductor devices. Such capacitive structures include, for example, metal-oxide-semiconductor (MOS) capacitors, p-n junction capacitors, and metal-insulator-metal (MIM) capacitors. MIM capacitors can be used in mixed signal devices and logic devices, such as embedded memories and radio frequency devices. MIM capacitors exhibit improved frequency and temperature characteristics. Furthermore, MIM capacitors are formed in or over the metal interconnect layers, thereby reducing CMOS transistor process integration interactions or complications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1G are cross-sectional side views of a metal-insulator-metal (MIM) capacitor device structure at various stages of fabrication, in accordance with some embodiments.

FIG. 1E-1 is an enlarged cross-sectional side view of a dielectric stack of the MIM capacitor device structure of FIG. 1E, in accordance with some embodiments.

FIG. 1E-2 is an enlarged cross-sectional side view of a dielectric stack formed on a conductive layer of the MIM capacitor device structure of FIG. 1E, in accordance with alternative embodiments.

FIG. 2 is a cross-sectional side view of the MIM capacitor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of present disclosure relate to MIM capacitor device structures and methods of manufacturing the MIM capacitor device structures. Some embodiments provide a MIM capacitor device structure including a dielectric stack formed between two conductive layers. The dielectric stack includes a high-k dielectric layer disposed between first and second dielectric layers. The first and second dielectric layers each has an oxygen concentration substantially greater than that of the high-k dielectric layer, and the first and second dielectric layers are formed by a plasma enhanced atomic layer deposition (PEALD) process. As a result, the first and second dielectric layers function as barrier layers to prevent inter-diffusion of metals between the conductive layers and the high-k dielectric layer, which reduces time dependent dielectric breakdown (TDDB) failure of the high-k dielectric layer. The total capacitance (Cₘᵢₘ) of the MIM capacitor is also improved with the dielectric stack.

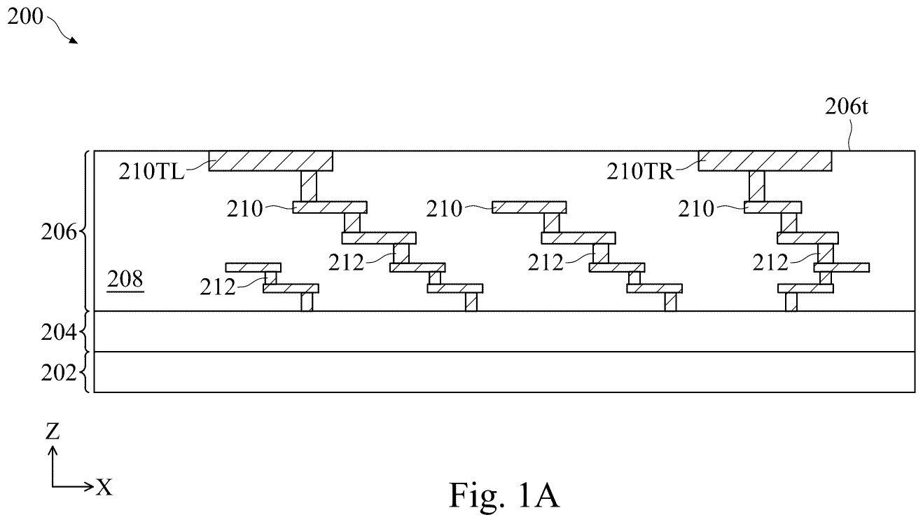

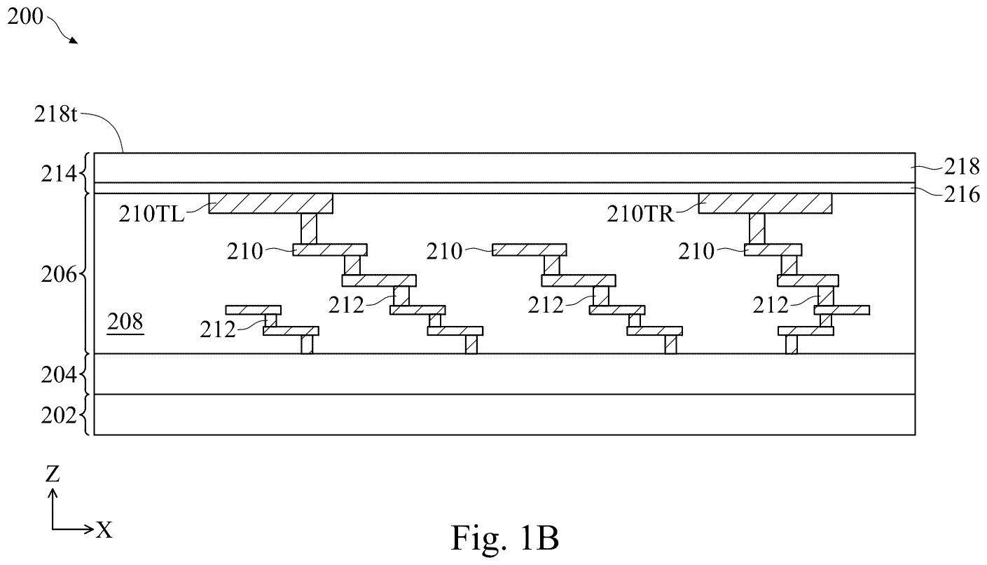

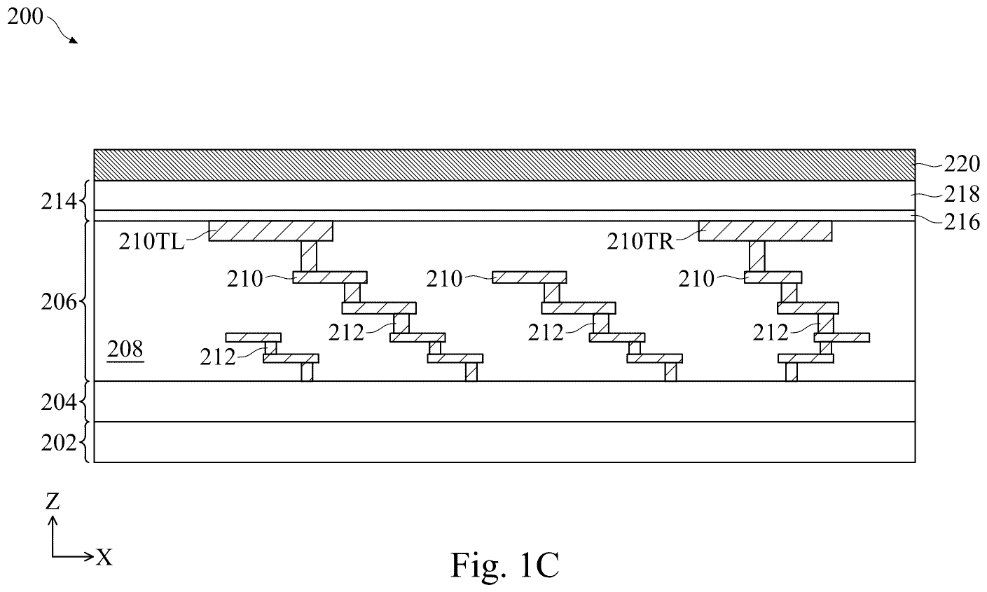

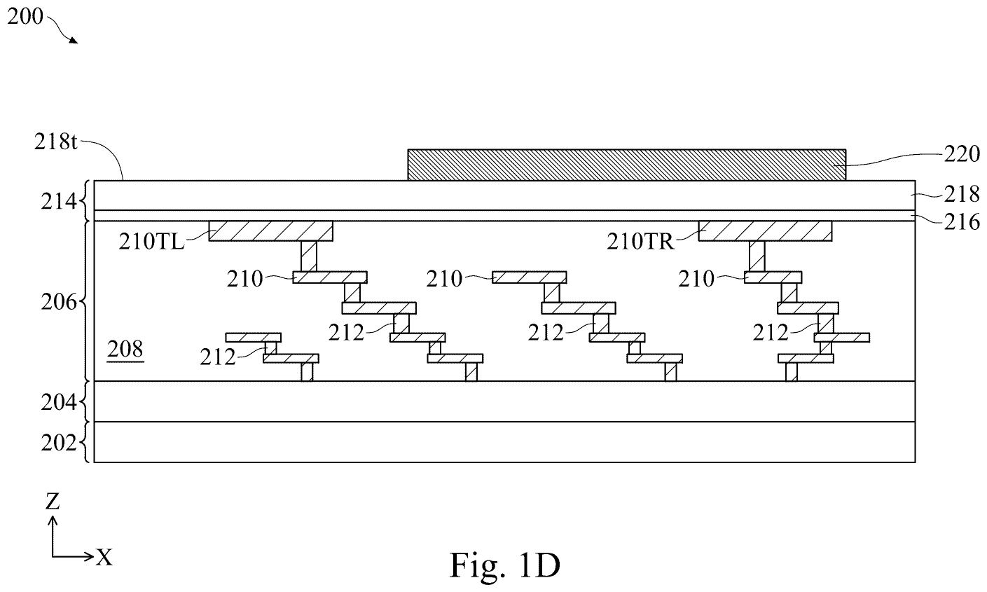

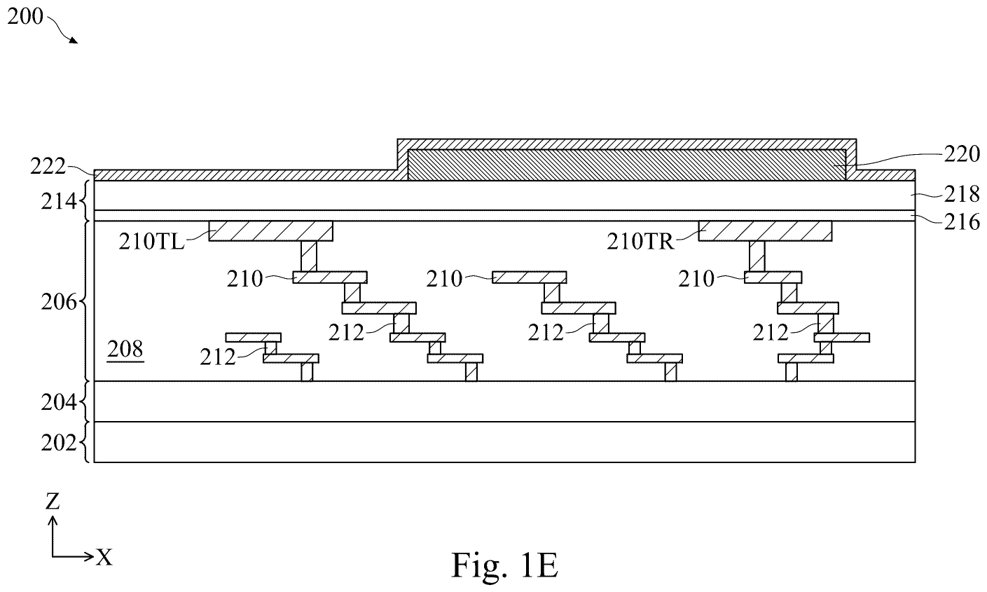

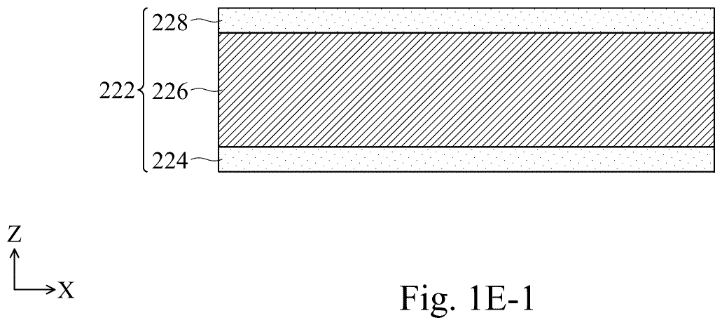

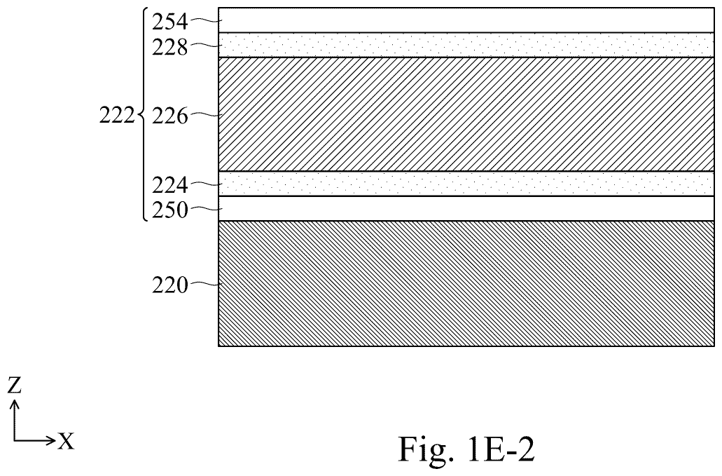

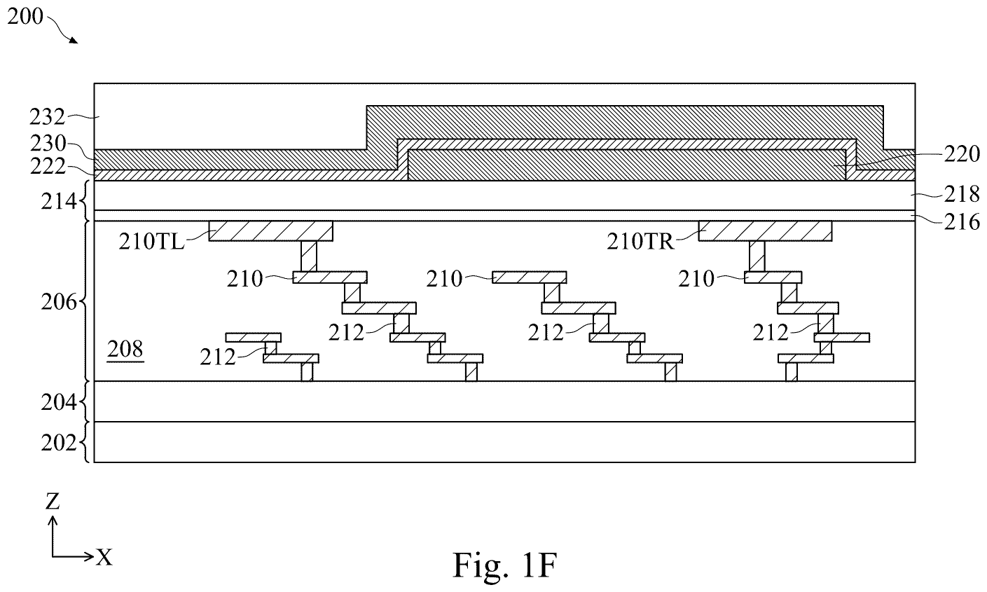

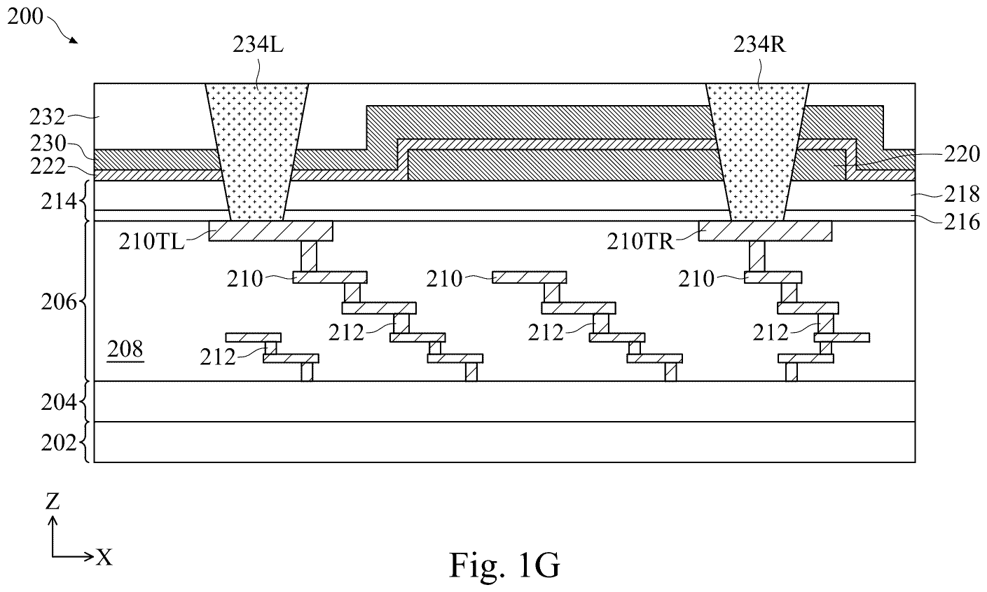

FIGS. 1A-1G are cross-sectional side views of a metal-insulator-metal (MIM) capacitor device structure 200 at various stages of fabrication, in accordance with some embodiments. It is understood that additional operations can be provided before, during, and after processes shown by FIGS. 1A-1G, and some of the operations described below can be replaced or eliminated, for additional embodiments of the method. The order of the operations/processes is not limiting and may be interchangeable.

As shown in FIG. 1A, the MIM capacitor device structure 200 includes a substrate 202, a device layer 204 formed in and/or on a front side of the substrate 202, and an interconnect structure 206 formed over the device layer 204. MIM capacitors may be formed on and within the interconnect structure 206.

In some embodiments, the substrate 202 may be a semiconductor substrate, such as a bulk semiconductor, a semiconductor-on-insulator (SOI) substrate, or the like, which may be doped, for example, with P-type or N-type dopants, or undoped. The substrate 202 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 202 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GalnAs, GaInP, and/or GaInAsP; or combinations thereof. The substrate 202 may further include isolation features (not shown), such as shallow trench isolation (STI) features or local oxidation of silicon (LOCOS) features. Isolation features may surround and isolate various device elements in the device layer 204.

The device layer 204 includes device elements formed in and/or on the substrate 202. Device elements may include transistors, such as metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc., diodes, and/or other applicable elements. In some embodiments, the device elements are formed in the substrate 202 in a front-end-of-line (FEOL) process.

The interconnect structure 206 includes various conductive features, such as a first plurality of conductive features 210 and second plurality of conductive features 212, and an intermetal dielectric (IMD) layer 208 to separate and isolate various conductive features 210, 212. In some embodiments, the first plurality of conductive features 210 are conductive lines and the second plurality of conductive features 212 are conductive vias. The interconnect structure 206 includes multiple levels of the conductive features 210, and the conductive features 210 are arranged in each level to provide electrical paths to various device elements in the device layer 204 disposed below. The conductive features 212 provide vertical electrical routing from the device layer 204 to the conductive features 210 and between conductive features 210. For example, the bottom-most conductive features 212 of the interconnect structure 206 may be electrically connected to the conductive contacts disposed over source/drain regions and gate electrodes of transistors in the device layer 204.

The IMD layer 208 includes one or more dielectric materials to provide isolation functions to various conductive features 210, 212. The IMD layer 208 may include multiple levels embedding multiple levels of conductive features 210, 212. A level of the interconnect structure 206 may be a layer of the IMD layer 208. The layers are sometimes referred to as M1, M2, . . . M10, M11, et, with M1 being closest to the device layer 204. In some embodiments, the conductive features 210 on the topmost IMD layer are referred to as top metal and denoted as conductive features 210TL, 210TR.

The IMD layer 208 may be made from a dielectric material, such as SiOx, SiOₓC_{y}H₂, SiOCN, SiON, or SiOₓC_{y}, where x, y and z are integers or non-integers. In some embodiments, the IMD layer 208 includes a low-k dielectric material having a k-value less than that of silicon dioxide. In some embodiments, the IMD layer 208 may include etch stop layers between levels of low-k dielectric material layers to facilitate patterning and formation of the conductive features 210, 212. The etch stop layers may be made of silicon carbide (SiC), silicon nitride (SiₓN_{y}), silicon carbonitride (SiCN), silicon oxycarbide (SiOC), silicon oxycarbon nitride (SiOCN), or another applicable material.

The conductive features 210 and conductive features 212 may be made from one or more electrically conductive materials, such as metal, metal alloy, metal nitride, or silicide. For example, the conductive features 210 and the conductive features 212 are made from copper, aluminum, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, iridium, other suitable conductive material, or a combination thereof. In some embodiments, a barrier layer, not shown, may be formed between the IMD layer 208 and the conductive features 210, 212 to prevent diffusion of the conductive features 210, 212 to the dielectric material in the IMD layer 208. The barrier layer may be made of titanium (Ti), titanium alloy, tantalum (Ta) or tantalum alloy. For example, the barrier layer may be made of tantalum nitride (TaN).

In some embodiments, a planarization process, a chemical mechanical polishing (CMP) process, and/or a cleaning process may be performed to expose the topmost conductive features 210T prior to forming the MIM capacitors. Two topmost conductive features 210TL and 210TR are shown and to connect with electrodes of the capacitor to be formed. As shown in FIG. 1A, the topmost conductive features 210TL and 201TR are exposed on a top surface 206t of the interconnect structure 206.

As shown in FIG. 1B, an insulation layer 214 is formed over the interconnect structure 206. In some embodiments, the insulation layer 214 may include an etch stop layer 216 and a dielectric layer 218 sequentially deposited over the interconnect structure 206. The etch stop layer 216 may include silicon carbide (SiC), silicon nitride (SiₓN_{y}), silicon carbonitride (SiCN), silicon oxycarbide (SiOC), silicon oxycarbon nitride (SiOCN), or another suitable material. In some embodiments, the etch stop layer 216 may be formed by performing a plasma enhanced chemical vapor deposition (CVD) process, a low-pressure CVD process, an atomic layer deposition (ALD) process, or another applicable process. In some embodiments, the thickness of the etch stop layer 216 is in a range from about 100 nm to about 200 nm.

The dielectric layer 218 may include undoped silicate glass (USG), fluorinated silicate glass (FSG), carbon-doped silicate glass, silicon oxide, silicon nitride or silicon oxynitride. In some embodiments, the dielectric layer 218 may be formed by a chemical vapor deposition (CVD) process, a spin-on process, a sputtering process, or a combination thereof. In some embodiments, the thickness of the dielectric layer 218 is in a range from about 400 nm to about 800 nm. The dielectric layer 218 may have a substantially planar top surface 218t, as shown in FIG. 1B.

As shown in FIG. 1C, a conductive layer 220 is deposited on the top surface 218t of the dielectric layer 218. The conductive layer 220 may be formed from a suitable electrically conductive material. In some embodiments, the conductive layer 220 is formed from titanium nitride (TiN), tantalum nitride (TaN), molybdenum nitride (MoN), or a combination thereof. In some embodiments, the conductive layer 220 may be formed by a physical vapor deposition (PVD) process, a CVD process, or an atomic layer deposition (ALD) process. The conductive layer 220 may have a thickness ranging from about 10 nm to about 100 nm.

As shown in FIG. 1D, the conductive layer 220 may be patterned. Processes such as photolithography process, maskless lithography process, etch process, or variety of processes suitable for transferring a pattern to the conductive layer may be performed. The patterned conductive layer 220 may be formed in a variety of shapes in the x-y plane (viewed from top), for example, a circle, a curvilinear shape, a rectangle, a line, a polygon including with rounded corners, and/or other suitable shapes. In some embodiment, the patterned conductive layer 220 overlaps with one of the topmost conductive features 210TL, 210TR. The patterned conductive layer 220 may function as a bottom electrode of an MIM capacitor. After the formation of the patterned conductive layer 220, a clean process may be performed to remove any etchant remaining in the processing chamber.

As shown in FIG. 1E, a dielectric stack 222 is formed over the dielectric layer 218 and the patterned conductive layer 220. FIG. 1E-1 is an enlarged cross-sectional side view of the dielectric stack 222 in accordance with some embodiments. As shown in FIG. 1E-1, the dielectric stack 222 includes a first dielectric layer 224, a high-k dielectric layer 226 formed on the first dielectric layer 224, and a second dielectric layer 228 formed on the high-k dielectric layer 226. The first and second dielectric layers 224, 228 may include any suitable dielectric material. In some embodiments, the first and second dielectric layers 224, 228 each includes a metal oxide. The metal of the metal oxide may be a transition metal (Ti, Cr, Mn, Fe, Co, Ni, Zn). In some embodiments, the first and second dielectric layers 224, 228 each includes TiOₓ, where x is an integer or a non-integer. For example, the first and second dielectric layers each includes TiO₂. The first and second dielectric layers 224, 228 are formed by PEALD.

The high-k dielectric layer 226 may function as the insulator of the MIM capacitor. In some embodiments, the high-k dielectric layer 226 includes dielectric materials having a dielectric constant (k) value in a range from about 10 to about 35. The high-k dielectric layer 226 may be oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu, or another suitable material. Exemplary high-k dielectric materials for the high-k dielectric layer 226 may include Al₂O₃, ZrO₂, Ta₂O₅, HfO₂, La₂O₃, TiO₂, SiO₂, or a combination hereof. In some embodiments, the high-k dielectric layer 226 includes HfO₂, ZrO₂, or HfₓZr₁₋ₓO₂ (0<x<1). In some embodiments, the high-k dielectric layer 226 is formed by a plasma enhanced chemical vapor deposition (PECVD) process, a low-pressure CVD (LPCVD) process, an atomic layer deposition (ALD) process, a molecular beam deposition (MBD) process, or another suitable process. In some embodiments, the high-k dielectric layer 226 has a thickness less than about 6 nm. In some embodiments, the high-k dielectric layer 226 is a crystalline high-k dielectric material and is deposited by ALD.

In some embodiments, without the first and second dielectric layers 224, 228, inter-diffusion of metals between the high-k dielectric layer 226 and the patterned conductive layers 220, 230 (FIG. 1F) may occur, which may result in TDDB failure of the high-k dielectric layer 226. The first and second dielectric layers 224, 228 can function as barrier layers to prevent the inter-diffusion of metals between the high-k dielectric layer 226 and the patterned conductive layers 220, 230. In some embodiments, the oxygen concentrations of the first and second dielectric layers 224, 228 are substantially greater than the oxygen concentration of the high-k dielectric layer 226. With the oxygen-rich first and second dielectric layers 224, 228, the inter-diffusion of metals between the high-k dielectric layer 226 and the patterned conductive layers 220, 230 may be minimized. It has been discovered that there is a trade-off between the thicknesses of the first and dielectric layers 224, 228 and the initial voltage of the MIM capacitor. In other words, as the thicknesses of the first and second dielectric layers 224, 228 increase, the initial voltage of the MIM capacitor also increases. Thus, in some embodiments, the thickness of each of the first and second dielectric layers 224, 228 ranges from about 4 Angstroms to about 15 Angstroms, such as from about 5 Angstroms to about 10 Angstroms. If the thicknesses of the first and second dielectric layers 224, 228 are less than about 5 Angstroms, such as less than about 4 Angstroms, the first and second dielectric layers 224, 228 may not properly function as barrier layers to prevent inter-diffusion of metals. On the other hand, if the thicknesses of the first and second dielectric layers 224, 228 are greater than about 10 Angstroms, such as about greater than about 15 Angstroms, the initial voltage of the MIM capacitor may be too high. In some embodiments, the first and second dielectric layers 224, 228 are formed by PEALD in order to have an improved control of the thicknesses of the first and second dielectric layers 224, 228. Furthermore, the quality of the first and second dielectric layers 224, 228 are improved as a result of the PEALD process, which in turn improves the barrier properties of first and second dielectric layers 224, 228. In some embodiments, the PEALD process includes a plasma power ranging from about 200 W to about 500 W, a process pressure ranging from about 2 torr to about 5 torr, and a process temperature ranging from about 150 degrees Celsius to about 400 degrees Celsius. In some embodiments, the thickness of the first dielectric layer 224 is substantially the same as the thickness of the second dielectric layer 228.

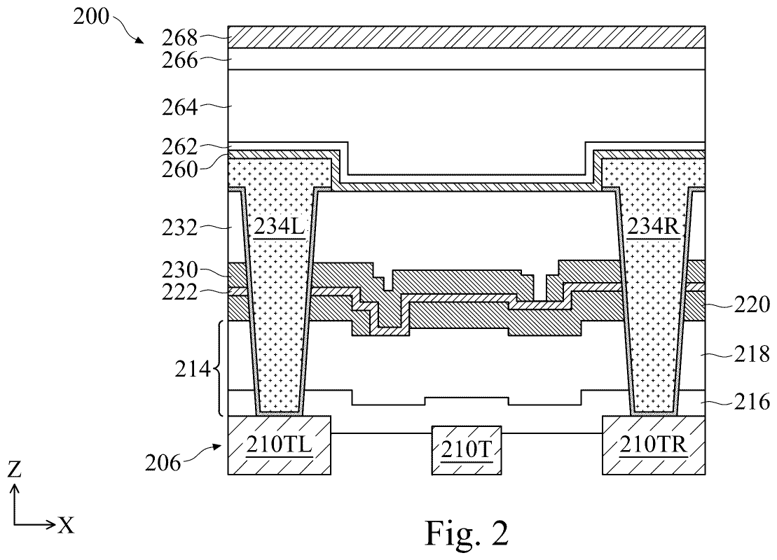

FIG. 1E-2 is an enlarged cross-sectional side view of the dielectric stack 222 formed on the patterned conductive layer 220 of the MIM capacitor device structure 100 of FIG. 1E, in accordance with alternative embodiments. In some embodiments, additional processes may be performed to further reduce the initial voltage. In some embodiments, prior to depositing the first dielectric layer 224, a plasma treatment is performed on the top surface of the patterned conductive layer 220. The plasma treatment may utilize a nitrogen-containing plasma, such as NH₃ plasma, N₂ plasma, or other suitable plasma. In some embodiments, the plasma treatment forms a layer 250 in the patterned conductive layer 220. For example, a top portion of the patterned conductive layer 220 is converted to the layer 250. In some embodiments, the patterned conductive layer 220 includes TiN having a first nitrogen concentration, and the layer 250 includes TiN having a second nitrogen concentration substantially greater than the first concentration. In some embodiments, the layer 250 is part of the dielectric stack 222. Next, the first dielectric layer 224 is deposited on the layer 250, the high-k dielectric layer 226 is deposited on the first dielectric layer 224, and the second dielectric layer 228 is deposited on the high-k dielectric layer 226, as shown in FIG. 1E-2. The dielectric stack 222 illustrated in FIGS. 1E-1 and 1E-2 can lead to reduced initial voltage, improved total capacitance, and reduced TDDB failure.

In some embodiments, after depositing the second dielectric layer 228, another plasma treatment is performed on the second dielectric layer 228 to form a layer 254. The plasma treatment may be the same as the plasma treatment performed on the patterned conductive layer 220. The plasma treatment converts a portion of the second dielectric layer 228 into the layer 254. The layer 254 may be a nitride layer. In some embodiments, the layer 254 includes a metal oxynitride, such as TiON. As described above, the thicknesses of the first and second dielectric layers 224, 228 are within a specific range to achieve lowered initial voltage while preventing inter-diffusion of metals. Thus, in some embodiments, the total thickness of the layer 250 and the first dielectric layer 224 is in a range from about 4 nm to about 15 nm, such as from about 5 nm to about 10 nm. Similarly, in some embodiments, the total thickness of the second dielectric layer 228 and the layer 254 is in a range from about 4 nm to about 15 nm, such as from about 5 nm to about 10 nm. In some embodiments, because the layer 254 is part of the second dielectric layer 228 prior to the plasma treatment, the thickness of the as-deposited second dielectric layer 228 is greater than the thickness of the first dielectric layer 224. In some embodiments, the as-deposited second dielectric layer 228 has a thickness substantially the same as the total thickness of the layer 250 and the first dielectric layer 224. The plasma treatment performed on the as-deposited second dielectric layer 228 converts a portion of the second dielectric layer 228 into the layer 254. In some embodiments, the thicknesses of the layer 254 and the second dielectric layer 228 after the plasma treatment are substantially the same.

With the addition of the layers 250, 254, the inter-diffusion of metals between the high-k dielectric layer 226 and the patterned conductive layers 220, 230 (FIG. 1F) is prevented, and the initial voltage is further reduced compared to the dielectric stack 222 shown in FIG. 1E. It is believed that the additional interfaces, such as the interface between the layer 250 and the first dielectric layer 224 and the interface between the second dielectric layer 228 and the layer 254, further reduces the initial voltage while not negatively affecting the barrier properties of the first and second dielectric layers 224, 228.

As shown in FIG. 1F, the conductive layer 230 is deposited on the dielectric stack 222. In some embodiments, the conductive layer 230 is deposited on the second layer 228 (FIG. 1E-1). In some embodiments, the conductive layer 230 is deposited on the layer 254 (FIG. 1E-2). The conductive layer 230 may include the same material as the conductive layer 220 and may be deposited by the same process as the conductive layer 220. The conductive layer 230 may have a thickness ranging from about 10 nm to about 100 nm. In some embodiments, the first and second conductive layers 220, 230 each includes TiN. The conductive layer 230 may be patterned, and the patterned second conductive layer 230 may function as a top electrode of the MIM capacitor. In some embodiments, the MIM capacitor includes the patterned conductive layer 220 as the bottom electrode, the dielectric stack 222 as the insulator, and the patterned conductive layer 230 as the top electrode. In some embodiments, the MIM capacitor is a symmetric structure with respect to a center line of the high-k dielectric layer 226.

As shown in FIG. 1F, a dielectric layer 232 is deposited on the patterned conductive layer 230. In some embodiments, the dielectric layer 232 may include the same material as the dielectric layer 218 and may be formed by the same process as the dielectric layer 218. In some embodiments, the dielectric layer 232 may include undoped silicate glass (USG), fluorinated silicate glass (FSG), carbon-doped silicate glass, silicon oxide, silicon nitride or silicon oxynitride. In some embodiments, the dielectric layer 232 may be formed by a chemical vapor deposition (CVD) process, a spin-on process, a sputtering process, or a combination thereof. In some embodiments, the thickness of the dielectric layer 232 is in a range from about 500 nm to about 1500 nm.

As shown in FIG. 1G, conductive features 234L, 234R are formed through the dielectric layer 232, the patterned conductive layer 230, the dielectric stack 222, the patterned conductive layer 220, and the insulation layer 214. In some embodiments, the conductive feature 234L is electrically connected to the conductive feature 210TL, and the conductive feature 234R is electrically connected to the conductive feature 210TR, as shown in FIG. 1G. The conductive features 234L, 234R each may include copper, aluminum, AlCu, and/or other suitable materials. In some embodiments, barrier layers, not shown, may be deposited in openings prior to forming the conductive features 234L, 234R, and the conductive features 234L, 234R are formed on the barrier layers. In some embodiments, the patterned conductive layer 230 electrically connected to the conductive feature 234L is the top electrode of the MIM capacitor, the high-k dielectric layer 226 is the insulator of the MIM capacitor, and the patterned conductive layer 220 electrically connected to the conductive feature 234R is the bottom electrode of the MIM capacitor. The conductive features 234L, 234R provide electrical connections to the MIM capacitor.

FIG. 2 is a cross-sectional side view of the MIM capacitor device structure 100, in accordance with some embodiments. As shown in FIG. 2, in some embodiments, the top surface of the interconnect structure 206 is not substantially flat. The etch stop 216 and the dielectric layer 218 may be conformal layers. As a result, the top surface of the dielectric layer 218 is also not flat, as shown in FIG. 2. In some embodiments, the patterned conductive layer 220 includes multiple portions of the conductive layer 220, and the patterned conductive layer 230 includes multiple portions of the conductive layer 230, as shown in FIG. 2. In some embodiments, the conductive features 234L, 234R each includes a top portion disposed on the dielectric layer 232 and a bottom portion disposed through the dielectric layer 232, the patterned conductive layer 230, the dielectric stack 222, the patterned conductive layer 220, and the insulation layer 214. After the formation of the conductive features 234L, 234R, multiple layers are formed over the conductive features 234L, 234R and the dielectric layer 232.

In some embodiments, as shown in FIG. 2, a first layer 260 is deposited on the conductive features 234L, 234R and the dielectric layer 232. The first layer 260 may be a seal layer and may include any suitable dielectric material. In some embodiments, the first layer 260 includes SiN and has a thickness ranging from about 100 nm to about 200 nm. A second layer 262 is deposited on the first layer 260. The second layer 262 may include any suitable dielectric material. In some embodiments, the second layer 262 includes undoped silicate glass (USG) and has a thickness ranging from about 150 nm to about 250 nm. A third layer 264 is deposited on the second layer 262. The third layer 264 may include any suitable dielectric material. In some embodiments, the third layer 264 includes high-density plasma (HDP) oxide and has a thickness ranging from about 2000 nm to about 3500 nm. A fourth layer 266 is deposited on the third layer 264. The fourth layer 266 may include any suitable dielectric material. In some embodiments, the fourth layer 266 includes USG and has a thickness ranging from about 1500 nm to about 2500 nm. A fifth layer 268 is deposited on the fourth layer 266. The fifth layer 268 may include any suitable dielectric material. In some embodiments, the fifth layer 268 includes SiN and has a thickness ranging from about 400 nm to about 1000 nm. The first, second, third, fourth, and fifth layers 260, 262, 264, 266, 268 may passivate the conductive features 234L, 234R. Subsequent processes may include forming openings in the first, second, third, fourth, and fifth layers 260, 262, 264, 266, 268 to expose the conductive features 234L, 234R and forming contacts in the openings.

Embodiments of the present disclosure provide the MIM capacitor device structure 200 and the methods of forming the same. In some embodiments, a dielectric stack 222 is disposed between two electrodes of the MIM capacitor. The dielectric stack 222 includes a high-k dielectric layer 226 disposed between first and second dielectric layers 224, 228. Oxygen concentrations of the first and second dielectric layers 224, 228 may be substantially greater than an oxygen concentration of the high-k dielectric layer 226. The first and second dielectric layers 224, 228 may be formed by PEALD. Some embodiments may achieve advantages. For example, the first and second dielectric layers 224, 228 can function as barrier layers to prevent inter-diffusion of metals between the two electrodes and the high-k dielectric layer 226. Furthermore, the first and second dielectric layers 224, 228 can lead to improved total capacitance and reduced initial voltage.

An embodiment is a MIM capacitor device structure. The structure includes a first conductive layer disposed over a substrate and a dielectric stack disposed on the first conductive layer. The dielectric stack includes a first dielectric layer disposed on the first conductive layer, and the first dielectric layer has a first oxygen concentration. The dielectric stack further includes a high-k dielectric layer disposed on the first dielectric layer, and the high-k dielectric layer has a second oxygen concentration different from the first oxygen concentration. The dielectric stack further includes a second dielectric layer disposed on the high-k dielectric layer, and the second dielectric layer has a third oxygen concentration different from the second oxygen concentration. The structure further includes a second conductive layer disposed on the dielectric stack.

Another embodiment is a MIM capacitor device structure. The structure includes a first conductive layer disposed over a substrate and a dielectric stack disposed on the first conductive layer. The dielectric stack includes a first layer disposed on the first conductive layer, and the first layer includes a first nitride. The dielectric stack further includes a first dielectric layer disposed on the first layer, and the first dielectric layer includes a first oxide. The dielectric stack further includes a high-k dielectric layer disposed on the first dielectric layer and a second dielectric layer disposed on the high-k dielectric layer. The second dielectric layer includes a second oxide. The dielectric stack further includes a second layer disposed on the second dielectric layer, and the second layer includes a second nitride. The structure further includes a second conductive layer disposed on the dielectric stack.

A further embodiment is a method. The method includes depositing a first conductive layer over a substrate and forming a dielectric stack on the first conductive layer. The forming of the dielectric stack includes depositing a first dielectric layer, and the first dielectric layer has a first oxygen concentration. The forming of the dielectric stack further includes depositing a high-k dielectric layer on the first dielectric layer, and the high-k dielectric layer has a second oxygen concentration different from the first oxygen concentration. The forming of the dielectric stack further includes depositing a second dielectric layer on the high-k dielectric layer, and the second dielectric layer has a third oxygen concentration different from the second oxygen concentration. The method further includes depositing a second conductive layer on the dielectric stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A structure, comprising:
a first conductive layer disposed over a substrate;
a dielectric stack disposed on the first conductive layer, wherein the dielectric stack comprises:
a first dielectric layer disposed on the first conductive layer, wherein the first dielectric layer has a first oxygen concentration;
a high-k dielectric layer disposed on the first dielectric layer, wherein the high-k dielectric layer has a second oxygen concentration different from the first oxygen concentration; and
a second dielectric layer disposed on the high-k dielectric layer, wherein the second dielectric layer has a third oxygen concentration different from the second oxygen concentration; and
a second conductive layer disposed on the dielectric stack.

2. The structure of claim 1, wherein the first and second dielectric layers each comprises a metal oxide.

3. The structure of claim 2, wherein the metal oxide comprises a transition metal.

4. The structure of claim 3, wherein the metal oxide comprises titanium.

5. The structure of claim 2, wherein the first and second dielectric layers each has a thickness ranging from about 4 nm to about 15 nm.

6. The structure of claim 2, wherein the first and second dielectric layers each has a thickness ranging from about 5 nm to about 10 nm.

7. The structure of claim 1, further comprising a first conductive feature and a second conductive feature, wherein the dielectric stack is disposed over the first and second conductive features.

8. The structure of claim 7, wherein comprising a third conductive feature and a fourth conductive feature, wherein the third conductive feature extends through the dielectric stack and the first conductive layer, the fourth conductive extends through the dielectric stack and the second conductive layer, the third conductive feature is electrically connected to the first conductive feature, and the fourth conductive feature is electrically connected to the second conductive feature.

9. A structure, comprising:
a first conductive layer disposed over a substrate;
a dielectric stack disposed on the first conductive layer, wherein the dielectric stack comprises:
a first layer disposed on the first conductive layer, wherein the first layer comprises a first nitride;
a first dielectric layer disposed on the first layer, wherein the first dielectric layer comprises a first oxide;
a high-k dielectric layer disposed on the first dielectric layer;
a second dielectric layer disposed on the high-k dielectric layer, wherein the second dielectric layer comprises a second oxide; and
a second layer disposed on the second dielectric layer, wherein the second layer comprises a second nitride; and
a second conductive layer disposed on the dielectric stack.

10. The structure of claim 9, wherein the first nitride comprises TiN.

11. The structure of claim 10, wherein the first and second oxides each comprises TiO.

12. The structure of claim 11, wherein the second nitride comprises TiON.

13. The structure of claim 9, wherein a total thickness of the first layer and the first dielectric layer is in a range from about 4 nm to about 15 nm.

14. The structure of claim 13, wherein a total thickness of the second layer and the second dielectric layer is in a range from about 4 nm to about 15 nm.

15. A method, comprising:
depositing a first conductive layer over a substrate;
forming a dielectric stack on the first conductive layer, comprising:
depositing a first dielectric layer, wherein the first dielectric layer has a first oxygen concentration;
depositing a high-k dielectric layer on the first dielectric layer, wherein the high-k dielectric layer has a second oxygen concentration different from the first oxygen concentration; and
depositing a second dielectric layer on the high-k dielectric layer, wherein the second dielectric layer has a third oxygen concentration different from the second oxygen concentration; and
depositing a second conductive layer on the dielectric stack.

16. The method of claim 15, further comprising performing a first plasma treatment on the first conductive layer prior to the depositing of the first dielectric layer.

17. The method of claim 16, wherein the first plasma treatment utilizes a nitrogen-containing plasma.

18. The method of claim 16, further comprising performing a second plasma treatment on the second dielectric layer prior to the depositing of the second conductive layer.

19. The method of claim 18, wherein a portion of the second dielectric layer is converted to a nitride layer by the second plasma treatment.

20. The method of claim 16, wherein the first and second dielectric layers are formed by plasma enhanced atomic layer deposition.
